(19) United States
(12) Patent Application Publication
(10) Pub. No.: US 2026/0160839 A1
(43) Pub. Date: Jun. 11, 2026

(54) GRADIENT MAGNETIC FIELD POWER SUPPLY APPARATUS AND GRADIENT MAGNETIC FIELD POWER SUPPLY CONTROL METHOD

(71) Applicant: CANON MEDICAL SYSTEMS CORPORATION, Otawara-shi (JP)

(72) Inventors: Motohiro MIURA, Yaita Tochigi (JP); Masaaki YAMANAKA, Otawara Tochigi (JP); Fumiyasu OTAKE, Sakura Tochigi (JP)

(73) Assignee: CANON MEDICAL SYSTEMS CORPORATION, Otawara-shi (JP)

(21) Appl. No.: 19/395,018

(22) Filed: Nov. 20, 2025

(30) Foreign Application Priority Data
Dec. 11, 2024 (JP) 2024-216373

(51) Int. Cl. G01R 33/385; G01R 33/36; G01R 33/54

(52) U.S. Cl. CPC G01R 33/3852; G01R 33/3614; G01R 33/543

(57) ABSTRACT

A gradient magnetic field power supply apparatus according to an embodiment includes first circuitry, a first detection unit, a second detection unit, and second circuitry. The first circuitry supplies a current to a first coil based on a first signal corresponding to the current to be supplied to the first coil configured to generate a gradient magnetic field. The first detection unit detects a current flowing through the first coil. The second detection unit detects a current flowing through a second coil configured to generate a gradient magnetic field. The second circuitry supplies a current to the second coil based on a second signal based on the first signal and a signal corresponding to a difference between the current detected by the first detection unit and the current detected by the second detection unit.

### CROSS-REFERENCE TO RELATED APPLICATIONS

This application is based upon and claims the benefit of priority from Japanese Patent Application No. 2024-216373, filed Dec. 11, 2024, the entire contents of which are incorporated herein by reference.

### FIELD

Embodiments described herein relate generally to a gradient magnetic field power supply apparatus and a gradient magnetic field power supply control method.

### BACKGROUND

A magnetic resonance imaging apparatus of related art is configured to capture an image of a subject using a gradient magnetic field system that generates a gradient magnetic field. The gradient magnetic field system includes a gradient magnetic field coil and a gradient magnetic field power supply that supplies electric current to the gradient magnetic field coil.

Such a magnetic resonance imaging apparatus is required to capture an image of the subject at a higher speed. To achieve this, the gradient magnetic field system is required to increase the strength of gradient magnetic field and improve a slew rate. For example, the strength of the gradient magnetic field can be increased and the slew rate of the gradient magnetic field system can be improved by increasing an output voltage and an output current of the gradient magnetic field power supply.

However, it is difficult to increase the output voltage and the output current of the gradient magnetic field power supply due to limitations of semiconductor elements.

### BRIEF DESCRIPTION OF THE DRAWINGS

FIG. 1 is a diagram illustrating an example of a magnetic resonance imaging (MRI) apparatus according to a first embodiment;

FIG. 2 is a diagram illustrating a circuitry configuration example of a gradient magnetic field system according to the first embodiment;

FIG. 3 is a diagram illustrating a circuitry configuration example of a gradient magnetic field system of related art;

FIG. 4 is a diagram illustrating an example of the gradient magnetic field system according to the first embodiment;

FIG. 5 is a diagram illustrating a circuitry configuration example of a gradient magnetic field system according to a first modified example; and

FIG. 6 is a diagram illustrating a circuitry configuration example of a gradient magnetic field system according to a second modified example.

### DETAILED DESCRIPTION

A gradient magnetic field power supply apparatus according to an embodiment includes first circuitry, a first detection unit, a second detection unit, and second circuitry. The first circuitry supplies a current to a first coil based on a first signal corresponding to the current to be supplied to the first coil configured to generate a gradient magnetic field. The first detection unit detects a current flowing through the first coil. The second detection unit detects a current flowing through a second coil configured to generate a gradient magnetic field. The second circuitry supplies a current to the second coil based on a second signal based on the first signal and a signal corresponding to a difference between the current detected by the first detection unit and the current detected by the second detection unit.

Various Embodiments will be described hereinafter with reference to the accompanying drawings.

In the following embodiments, parts denoted by the same reference numerals are assumed to perform similar operations, and redundant descriptions thereof are omitted as appropriate.

### First Embodiment

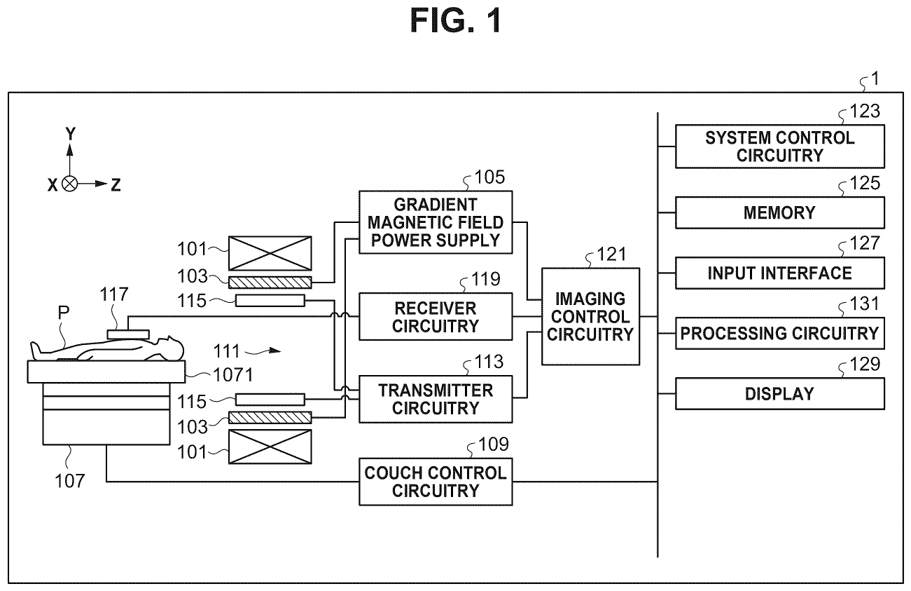

FIG. 1 is a diagram illustrating an example of a magnetic resonance imaging (MRI) apparatus 1 according to a first embodiment. As illustrated in FIG. 1, the MRI apparatus 1 includes a static magnetic field magnet 101, a gradient magnetic field coil 103, a gradient magnetic field power supply 105, a couch 107, couch control circuitry 109, transmitter circuitry 113, a transmission coil 115, a reception coil 117, receiver circuitry 119, imaging control circuitry 121, system control circuitry 123, a memory 125, an input interface 127, a display 129, and processing circuitry 131. The MRI apparatus 1 is an example of a magnetic resonance imaging apparatus.

The static magnetic field magnet 101 is a magnet formed in a hollow cylindrical shape. The static magnetic field magnet 101 generates a substantially uniform static magnetic field in an internal space. For example, a superconducting magnet or the like is used as the static magnetic field magnet 101.

The gradient magnetic field coil 103 is a coil formed in a hollow, substantially cylindrical shape, and is disposed on the inner surface of a cylindrical cooling container. The gradient magnetic field coil 103 includes three coils respectively corresponding to an X-axis, a Y-axis, and a Z-axis that are orthogonal to each other. The three coils in the gradient magnetic field coil 103 are individually supplied with a current from the gradient magnetic field power supply 105, and generate gradient magnetic fields with varying magnetic field intensities along the X-axis, the Y-axis, and the Z-axis, respectively, which are orthogonal to each other. The gradient magnetic fields corresponding to the X-axis, the Y-axis, and the Z-axis that are generated by the gradient magnetic field coil 103 form, for example, a slice selection gradient magnetic field, a phase encoding gradient magnetic field, and a frequency encoding gradient magnetic field. The slice selection gradient magnetic field is used to arbitrarily determine an imaging cross-section. The phase encoding gradient magnetic field is used to change a phase of a magnetic resonance (MR) signal according to a spatial position. The frequency encoding gradient magnetic field is used to change the frequency of the MR signal according to a spatial position.

The gradient magnetic field power supply 105 is a power supply apparatus that supplies electric current to the gradient magnetic field coil 103 under the control of the imaging control circuitry 121.

The couch 107 is an apparatus including a couchtop 1071 on which a subject P is placed. The couch 107 inserts the couchtop 1071 on which the subject P is placed into a bore 111 under the control of the couch control circuitry 109.

The couch control circuitry 109 is circuitry that controls the couch 107. The couch control circuitry 109 drives the couch 107 according to an instruction from an operator via the input interface 127 to thereby move the couchtop 1071 in the longitudinal direction and the vertical direction, and in the lateral direction in some cases.

The transmitter circuitry 113 supplies the transmission coil 115 with a high-frequency pulse modulated at the Larmor frequency under the control of the imaging control circuitry 121. For example, the transmitter circuitry 113 includes an oscillation unit, a phase selection unit, a frequency conversion unit, an amplitude modulation unit, and a radio frequency (RF) amplifier. The oscillation unit generates an RF pulse at a resonance frequency specific to a target atomic nucleus in the static magnetic field. The phase selection unit selects the phase of the RF pulse generated by the oscillation unit. The frequency conversion unit converts the frequency of the RF pulse output from the phase selection unit. The amplitude modulation unit modulates the amplitude of the RF pulse output from the frequency conversion unit, for example, based on a sinc function. The RF amplifier amplifies the RF pulse output from the amplitude modulation unit and supplies the amplified RF pulse to the transmission coil 115.

The transmission coil 115 is an RF coil disposed inside the gradient magnetic field coil 103. The transmission coil 115 generates a RF pulse corresponding to a high-frequency magnetic field in accordance with an output from the transmitter circuitry 113.

The reception coil 117 is an RF coil disposed inside the gradient magnetic field coil 103. The reception coil 117 receives MR signals emitted from the subject P due to a high-frequency magnetic field. The reception coil 117 outputs the received MR signals to the receiver circuitry 119. The reception coil 117 is, for example, a coil array including one or more, or typically two or more coil elements (hereinafter referred to as a plurality of coils). In the following description, the reception coil 117 is described as a coil array including the plurality of coils, for the purpose of providing a more specific description.

While, in FIG. 1, the transmission coil 115 and the reception coil 117 are described as individual RF coils, the transmission coil 115 and the reception coil 117 may be implemented as an integrated transmission/reception coil. The transmission/reception coil corresponds to an imaging site of the subject P and is, for example, a localized transmission/reception RF coil such as a head coil.

The receiver circuitry 119 generates digital MR signals (hereinafter referred to as MR data) based on the MR signals output from the reception coil 117, under the control of the imaging control circuitry 121. Specifically, the receiver circuitry 119 performs signal processing, such as detection and filtering, on the MR signals output from the reception coil 117, and performs an analog-to-digital (A/D) conversion on data subjected to the signal processing, thereby generating MR data. The receiver circuitry 119 outputs the generated MR data to the imaging control circuitry 121. For example, the MR data is generated in each of the plurality of coils and is output to the imaging control circuitry 121 together with tags for identifying the plurality of coils.

The imaging control circuitry 121 controls the gradient magnetic field power supply 105, the transmitter circuitry 113, the receiver circuitry 119, and the like in accordance with an imaging protocol output from the processing circuitry 131, and captures an image of the subject P. The imaging protocol includes a pulse sequence corresponding to the type of examination. The imaging protocol defines a magnitude of electric current to be supplied from the gradient magnetic field power supply 105 to the gradient magnetic field coil 103, a timing at which the electric current is supplied from the gradient magnetic field power supply 105 to the gradient magnetic field coil 103, a magnitude and a duration of a high-frequency pulse to be supplied to the transmission coil 115 by the transmitter circuitry 113, a timing at which a high-frequency pulse is supplied to the transmission coil 115 by the transmitter circuitry 113, and a timing at which an MR signal is received by the reception coil 117. The imaging control circuitry 121 drives the gradient magnetic field power supply 105, the transmitter circuitry 113, the receiver circuitry 119, and the like to capture an image of the subject P, receives resultant MR data from the receiver circuitry 119, and transfers the received MR data to the processing circuitry 131.

The imaging control circuitry 121 may collect MR data related to the generation of an image representing distribution of sensitivity of the reception coil 117 used to capture an image of the subject P by any imaging method. An image indicating the coil sensitivity is expressed as complex number data. The collection of the MR data related to the generation of an image representing distribution of sensitivity of the reception coil 117 is performed by the imaging control circuitry 121, for example, in a pre-scan, including a locator scan, prior to scanning the subject P. The imaging control circuitry 121 is implemented by, for example, a processor.

The term “processor” refers to, for example, circuitry such as a central processing unit (CPU), a graphics processing unit (GPU), an application specific integrated circuit (ASIC), a programmable logic device (e.g., a simple programmable logic device (SPLD), and a complex programmable logic device (CPLD), a field programmable gate array (FPGA)).

The system control circuitry 123 includes a processor and a memory, such as a read-only memory (ROM) or a random-access memory (RAM), as hardware resources, and controls the MRI apparatus 1 by a system control function. Specifically, the system control circuitry 123 reads out a system control program stored in the memory, loads the system control program into the memory, and controls each circuitry of the MRI apparatus 1 according the loaded system control program.

For example, the system control circuitry 123 reads out an imaging protocol from the memory 125 based on imaging conditions input from the operator via the input interface 127. The system control circuitry 123 transmits the imaging protocol to the imaging control circuitry 121 and controls imaging of the subject P. The system control circuitry 123 is implemented by, for example, a processor. The system control circuitry 123 may be incorporated in the processing circuitry 131. In this case, the system control function is executed by the processing circuitry 131, and the processing circuitry 131 functions as a substitute for the system control circuitry 123. The processor that implements the system control circuitry 123 is similar to that described above, and thus the description thereof is omitted.

The memory 125 stores various programs related to the system control function to be executed by the system control circuitry 123, various imaging protocols, imaging conditions including a plurality of imaging parameters defining the imaging protocols, and the like. The memory 125 also stores various functions to be implemented by the processing circuitry 131 in the form of a program that can be executed by a computer.

The memory 125 may store various data received via a communication interface (not illustrated). For example, the memory 125 stores information related to an examination order of the subject P (an imaging target site, an examination purpose, etc.) received from an information processing system such as a radiology information system (RIS) installed in a medical institution.

The memory 125 is implemented by, for example, a semiconductor memory element, such as a ROM, a RAM, and a flash memory, a hard disk drive (HDD), a solid state drive (SSD), and an optical disk. The memory 125 may also be implemented by a driving apparatus or the like that reads and writes various kinds of information from and to portable storage media such as a compact disc (CD)-ROM drive, a digital versatile disc (DVD) drive, and a flash memory.

The input interface 127 receives various instructions (e.g., a power-on instruction) from the operator. The input interface 127 is implemented by, for example, a trackball, a switch button, a mouse, a keyboard, a touch pad that allows an input operation by touching an operation surface thereof, a touch screen in which a display screen and a touch pad are integrated, non-contact input circuitry using an optical sensor, voice input circuitry, and the like. The input interface 127 is connected to the processing circuitry 131, converts an input operation received from the operator into an electric signal, and outputs the electric signal to the processing circuitry 131. In this specification, the input interface 127 is not limited only to an input interface including a physical operation component such as a mouse or a keyboard. Examples of the input interface 127 also include processing circuitry that receives an electric signal corresponding to an input operation from an external input device provided separately from the MRI apparatus 1 and outputs the electric signal to control circuitry.

The input interface 127 inputs a field of view (FOV) to a pre-scan image displayed on the display 129 according to an instruction from a user. Specifically, the input interface 127 inputs the FOV according to a range setting instruction from the user in a locator image displayed on the display 129. The input interface 127 inputs various imaging parameters related to scanning according to an instruction from the user based on the examination order.

The display 129 displays various graphical user interfaces (GUIs), MR images generated by the processing circuitry 131, and the like under the control of the processing circuitry 131 or the system control circuitry 123. The display 129 displays imaging parameters related to scanning, various kinds of information related to image processing, and the like. The display 129 is implemented by, for example, a display device such as a cathode-ray tube (CRT) display, a liquid crystal display, an organic electroluminescence (EL) display, a light-emitting diode (LED) display, a plasma display, or any other display or monitor known in this technical field.

The processing circuitry 131 is implemented by, for example, the above-described processor or the like. The processing circuitry 131 includes various functions and the like. Various functions are stored in the memory 125 in the form of a program that can be executed by a computer. For example, the processing circuitry 131 reads out programs from the memory 125, and executes the programs, thereby implementing the functions respectively corresponding to the programs. In other words, the processing circuitry 131, in a state where each program is read out, comes to have various functions.

In the description above, an example where the “processor” reads out the programs corresponding to the respective functions from the memory 125 and executes the programs has been described, but the embodiment is not limited thereto. In a case where the processor is, for example, a CPU, the processor reads out programs stored in the memory 125 and executes the programs, thereby implementing the functions. On the other hand, in a case where the processor is an ASIC, the functions are directly incorporated as logic circuitry in circuitry of the processor, instead of storing the programs in the memory 125. Each processor according to the present embodiment may be configured not only as a single piece of circuitry per processor, but also by combining a plurality of independent pieces of circuitry to constitute a single processor, to thereby implement the functions. While a single piece of storage circuitry has been described as storing programs corresponding to respective processing functions, a plurality of pieces of storage circuitry may be disposed in a distributed manner, and the processing circuitry 131 may be configured to read out the corresponding program from the individual piece of storage circuitry.

Next, a gradient magnetic field system 1000 will be described.

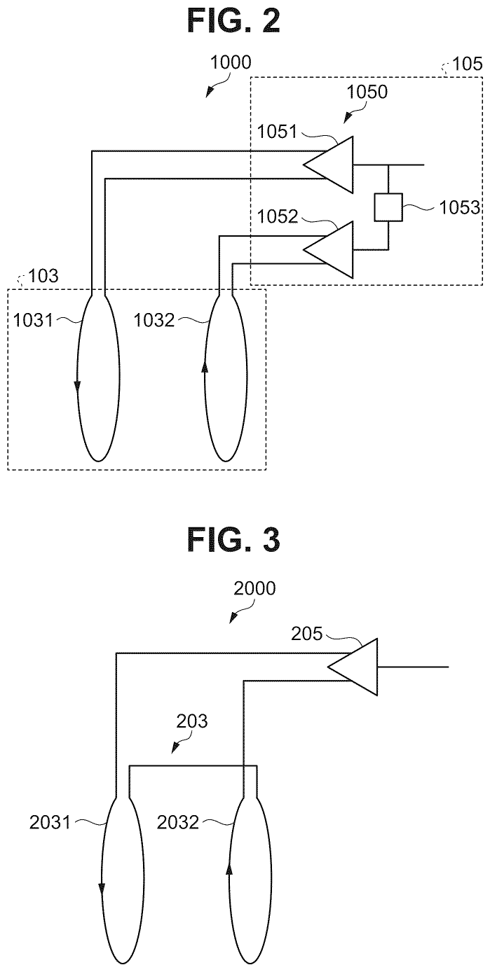

FIG. 2 is a diagram illustrating a circuitry configuration example of the gradient magnetic field system 1000 according to the first embodiment. FIG. 3 is a diagram illustrating a circuitry configuration example of a gradient magnetic field system 2000 of related art. In this case, the MRI apparatus 1 generates an X-axis gradient magnetic field, a Y-axis gradient magnetic field, and a Z-axis gradient magnetic field. The MRI apparatus 1 includes the gradient magnetic field system 1000 for each of the X-axis, the Y-axis, and the Z-axis of the gradient magnetic fields. The gradient magnetic field system 1000 illustrated in FIG. 2 is a system that generates the Z-axis gradient magnetic field. In the first embodiment, the gradient magnetic field system 1000 that generates the Z-axis gradient magnetic field will be described as an example. A system that generates the X-axis gradient magnetic field and a system that generates the Y-axis gradient magnetic field are also each implemented by a configuration similar to the gradient magnetic field system 1000.

The gradient magnetic field system 1000 according to the first embodiment includes signal adjustment circuitry 1053, a first amplifier unit 1051, a second amplifier unit 1052, a first gradient magnetic field coil 1031, and a second gradient magnetic field coil 1032. The signal adjustment circuitry 1053, the first amplifier unit 1051, and the second amplifier unit 1052 may be a part of the gradient magnetic field power supply 105, or may be provided separately from the gradient magnetic field power supply 105. The first gradient magnetic field coil 1031 and the second gradient magnetic field coil 1032 are parts of the gradient magnetic field coil 103. In other words, the gradient magnetic field system 1000 is a system including the gradient magnetic field power supply 105 and the gradient magnetic field coil 103. On the other hand, the gradient magnetic field system 2000 of related art includes an amplifier unit 205 and a gradient magnetic field coil 203.

The gradient magnetic field coil 203 of related art includes a first coil pattern 2031 and a second coil pattern 2032. The first coil pattern 2031 and the second coil pattern 2032 are connected in series. The gradient magnetic field is obtained by combining magnetic fields generated by the first coil pattern 2031 and the second coil pattern 2032 according to position. The first coil pattern 2031 and the second coil pattern 2032 are arranged side by side such that their central axes are in the same direction.

In the amplifier unit 205 of related art, a current flowing through the first coil pattern 2031 is identical to a current flowing through the second coil pattern 2032. A gradient magnetic field center of the gradient magnetic field generated by the current is constantly formed at the same position, and the magnitude of the gradient magnetic field is symmetrical about the gradient magnetic field center depending on a coil pattern.

In the gradient magnetic field system 2000 of related art, an output voltage and an output current from the amplifier unit 205 cannot be easily increased due to limitations of semiconductor elements.

The gradient magnetic field system 1000 according to the first embodiment includes the first gradient magnetic field coil 1031 and the second gradient magnetic field coil 1032. The first gradient magnetic field coil 1031 and the second gradient magnetic field coil 1032 correspond to coils for generating the Z-axis gradient magnetic field in the gradient magnetic field coil 103. The first gradient magnetic field coil 1031 and the second gradient magnetic field coil 1032 are arranged side by side such that their central axes are in the same direction.

The gradient magnetic field system 1000 according to the first embodiment includes the first amplifier unit 1051 and the second amplifier unit 1052. The first amplifier unit 1051 is circuitry that supplies a current to the first gradient magnetic field coil 1031. The second amplifier unit 1052 is circuitry that supplies a current to the second gradient magnetic field coil 1032.

The first gradient magnetic field coil 1031 and the second gradient magnetic field coil 1032 are each obtained by dividing the gradient magnetic field coil 203 of related art. Accordingly, the first gradient magnetic field coil 1031 and the second gradient magnetic field coil 1032 have an inductance smaller than that of the gradient magnetic field coil 203 of related art. When the current flowing through each of the first gradient magnetic field coil 1031 and the second gradient magnetic field coil 1032 is changed, a voltage corresponding to the product of the rate of change of the current and the inductance is required. Accordingly, the rate of change of the current when a voltage of a predetermined magnitude is applied to each of the first gradient magnetic field coil 1031 and the second gradient magnetic field coil 1032 is larger than the rate of change of the current when the voltage of the predetermined magnitude is applied to the gradient magnetic field coil 203 of related art. In other words, the configuration illustrated in FIG. 2 makes it possible to obtain a higher slew rate than that in the configuration of related art.

The first amplifier unit 1051 and the second amplifier unit 1052 are individual pieces of circuitry. Accordingly, a timing at which a current, or a signal, is supplied to the first gradient magnetic field coil 1031 is slightly different from a timing at which a current, or a signal, is supplied to the second gradient magnetic field coil 1032.

If the timing of supplying the current, or the signal, to each of the first gradient magnetic field coil 1031 and the second gradient magnetic field coil 1032 varies, the gradient magnetic field is not stabilized. In particular, if the timings of supplying the signal to each of the first gradient magnetic field coil 1031 and the second gradient magnetic field coil 1032 varies, the gradient magnetic field center moves over time. This causes deterioration in image quality. The term “gradient magnetic field center” herein refers to the spatial center of the gradient magnetic field generated by the first gradient magnetic field coil 1031 and the second gradient magnetic field coil 1032.

In the gradient magnetic field system 1000 according to the present embodiment, the following configuration suppresses variations in the current to be supplied to each of the first gradient magnetic field coil 1031 and the second gradient magnetic field coil 1032. In other words, in the gradient magnetic field system 1000 according to the present embodiment, the following configuration prevents deterioration in image quality.

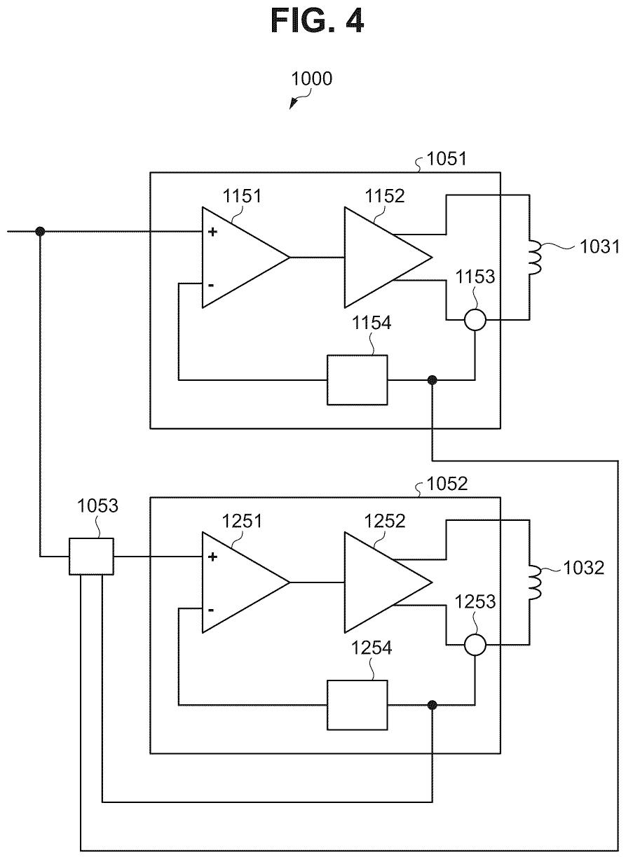

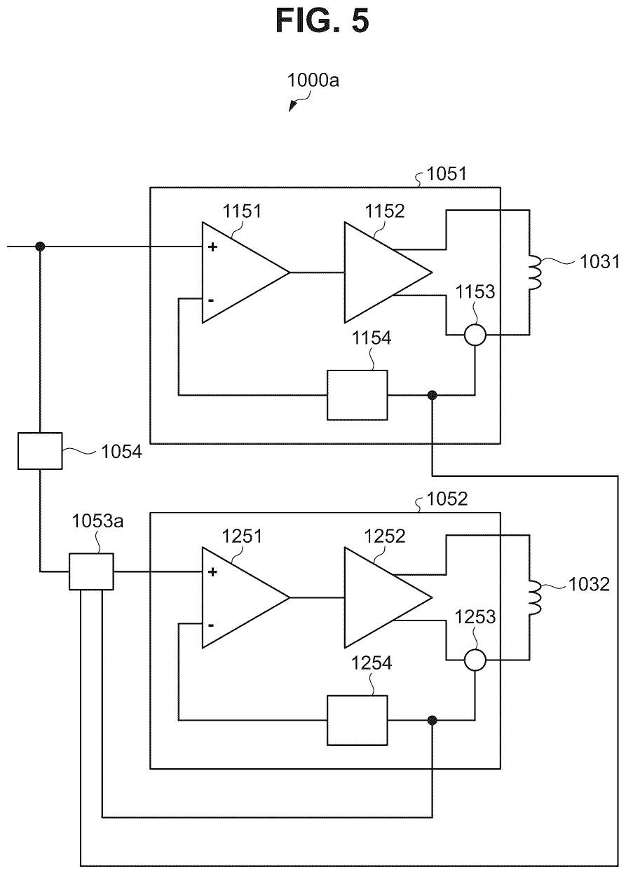

FIG. 4 is a diagram illustrating an example of the gradient magnetic field system 1000 according to the first embodiment.

The first amplifier unit 1051 obtains a command signal corresponding to a current to be supplied from the imaging control circuitry 121 to the first gradient magnetic field coil 1031. The first amplifier unit 1051 generates a current that generates a gradient magnetic field, i.e., a first gradient magnetic field generation signal, according to the command signal, and outputs the generated first gradient magnetic field generation signal to the first gradient magnetic field coil 1031.

More specifically, the first amplifier unit 1051 includes a first error amplifier 1151, a first power amplifier 1152, a first current sensor 1153, and first feedback circuitry 1154.

The first current sensor 1153 is a sensor that detects a current flowing through the first gradient magnetic field coil 1031. The first current sensor 1153 is an example of a first detection unit. The first feedback circuitry 1154 outputs a signal obtained by multiplying a signal detected by the first current sensor 1153 by a predetermined gain.

The first error amplifier 1151 outputs an error between the command signal and the signal output from the first feedback circuitry 1154.

The first power amplifier 1152 amplifies the signal output from the first error amplifier 1151, and outputs the amplified signal to the first gradient magnetic field coil 1031. Specifically, the first power amplifier 1152 supplies the first gradient magnetic field coil 1031 with a current generated so as to decrease a difference between the command signal and the signal corresponding to the current detected by the first current sensor 1153. The first error amplifier 1151 and the first power amplifier 1152 are examples of first circuitry.

A loop formed by the first error amplifier 1151, the first power amplifier 1152, the first current sensor 1153, and the first feedback circuitry 1154 forms a current source that outputs, to the first gradient magnetic field coil 1031, a current proportional to a positive input voltage (command signal to instruct generation of a gradient magnetic field) of the first error amplifier 1151.

The first gradient magnetic field coil 1031 generates a gradient magnetic field based on the current supplied from the first power amplifier 1152, i.e., the first gradient magnetic field generation signal. The first gradient magnetic field coil 1031 is an example of a first coil.

The signal adjustment circuitry 1053 is circuitry that generates an adjusted signal obtained by adjusting the command signal. For example, the signal adjustment circuitry 1053 may be implemented by digital circuitry, or may be implemented by analog circuitry. The signal adjustment circuitry 1053 is circuitry that inverts the command signal to minimize a difference between output currents from the first amplifier unit 1051 and the second amplifier unit 1052 due to variations. The adjusted signal is a signal obtained by combining the command signal with a signal corresponding to a difference between the current detected by the first current sensor 1153 and a current detected by a second current sensor 1253.

The signal adjustment circuitry 1053 supplies the second amplifier unit 1052 with an adjusted signal corresponding to a calculated value calculated by Expression (1) below. In Expression (1), an input of the first error amplifier 1151 represents a current value of the command signal, I₁ represents the output current of the first gradient magnetic field coil 1031 that is detected by the first current sensor 1153, I₂ represents the output current of the second gradient magnetic field coil 1032 detected by the second current sensor 1253, and G represents a gain. The gain can be as large as possible; however, the gain G at which the output current I₁ and the output current I₂ sufficiently match each other is determined while the actual output current I₁ and output current I₂ are observed.

$$( Input of First Error Amplifier 1151 ) + ( {I}_{1} - {I}_{2} ) \times G \qquad ( 1 )$$

As represented by Expression (1), the signal adjustment circuitry 1053 outputs, to the second amplifier unit 1052, the adjusted signal obtained by adding the difference between the output current I₁ of the first gradient magnetic field coil 1031 and the output current I₂ of the first gradient magnetic field coil 1031 to the command signal.

The second current sensor 1253 is a sensor that detects a current flowing through the second gradient magnetic field coil 1032. The second current sensor 1253 is an example of a second detection unit. Second feedback circuitry 1254 outputs a signal obtained by multiplying the signal detected by the second current sensor 1253 by a predetermined gain. A second error amplifier 1251 outputs an error between the adjusted signal and the signal output from the second feedback circuitry 1254.

A second power amplifier 1252 amplifies the signal output from the second error amplifier 1251, and outputs the amplified signal to the second gradient magnetic field coil 1032. Specifically, the second power amplifier 1252 supplies the second gradient magnetic field coil 1032 with a current generated so as to decrease a difference between the adjusted signal and the signal corresponding to the current detected by the second current sensor 1253. The second error amplifier 1251 and the second power amplifier 1252 are examples of second circuitry. The adjusted signal is an example of a second signal. More specifically, the second error amplifier 1251 and the second power amplifier 1252 supply power to the second gradient magnetic field coil 1032 depending on the product of the gain and the difference between the adjusted signal and the signal corresponding to the current detected by the second current sensor 1253.

The second gradient magnetic field coil 1032 generates a gradient magnetic field based on a current supplied from the second power amplifier 1252, i.e., a second gradient magnetic field generation signal. The second gradient magnetic field coil 1032 is an example of a second coil.

In the first embodiment, the gradient magnetic field system 1000 that generates the Z-axis gradient magnetic field has been described above as an example. The system that generates the X-axis gradient magnetic field and the system that generates the Y-axis gradient magnetic field are also each implemented by a configuration similar to the gradient magnetic field system 1000. In other words, the first gradient magnetic field coil 1031 and the second gradient magnetic field coil 1032 each generate a gradient magnetic field in any one of the three axial directions intersecting each other.

As described above, the gradient magnetic field coils corresponding to the X-axis, the Y-axis, and the Z-axis, respectively, according to the present embodiment include the first gradient magnetic field coil 1031 and the second gradient magnetic field coil 1032, and the MRI apparatus 1 includes the first amplifier unit 1051 corresponding to the first gradient magnetic field coil 1031 and the second amplifier unit 1052 corresponding to the second gradient magnetic field coil 1032. This configuration allows the inductance to be lower than the inductance of the gradient magnetic field coil 203 of related art. As a result, the slew rate in each of the first gradient magnetic field coil 1031 and the second gradient magnetic field coil 1032 can be improved.

In the present embodiment, the first amplifier unit 1051 supplies a current to the first gradient magnetic field coil 1031 based on the command signal, and the second amplifier unit 1052 supplies a current to the second gradient magnetic field coil 1032 based on the adjusted signal. The adjusted signal is a signal obtained by combining the command signal with the signal corresponding to the difference between the current detected by the first current sensor 1153 and the current detected by the second current sensor 1253. With this configuration, the degree of matching between the first gradient magnetic field generation signal and the second gradient magnetic field generation signal can be improved. In other words, this configuration makes it possible to prevent deterioration in image quality while improving the slew rate.

### First Modified Example

FIG. 5 is a diagram illustrating a circuitry configuration example of a gradient magnetic field system 1000a according to a first modified example. The gradient magnetic field system 1000a includes a timing adjustment circuitry 1054 between a command signal input terminal and a signal adjustment circuitry 1053a.

In this case, if the gain in Expression (1) is increased in a state where a difference between the timing of supplying the command signal to the first amplifier unit 1051 and the timing of supplying the command signal to the signal adjustment circuitry 1053a is large, the adjusted signal can be oscillated. Accordingly, the timing adjustment circuitry 1054 adjusts the timing of supplying the command signal to the signal adjustment circuitry 1053a.

The timing adjustment circuitry 1054 adjusts the timing of supplying the command signal so that the difference between the output current I₁ and the output current I₂ is decreased. With this configuration, the timing adjustment circuitry 1054 can prevent the possibility that the adjusted signal oscillates even when the gain in Expression (1) is increased. As a result, the timing adjustment circuitry 1054 can improve the degree of matching between the first gradient magnetic field generation signal and the second gradient magnetic field generation signal.

For example, the timing adjustment circuitry 1054 advances the timing of supplying the command signal to the signal adjustment circuitry 1053a. Alternatively, the timing adjustment circuitry 1054 delays the timing of supplying the command signal to the signal adjustment circuitry 1053a.

For example, the timing adjustment circuitry 1054 delays the command signal by, for example, delay circuitry. This enables the timing adjustment circuitry 1054 to delay the timing of supplying the command signal to the signal adjustment circuitry 1053a.

In this case, a timing at which the command signal is output is determined by the imaging sequence for capturing an image of the subject P. Accordingly, if an imaging sequence is selected, the timing adjustment circuitry 1054 supplies the signal adjustment circuitry 1053a with the command signal earlier than the output timing determined by the selected imaging sequence. Thus, the timing adjustment circuitry 1054 can advance the timing of supplying the command signal to the signal adjustment circuitry 1053a.

The timing adjustment circuitry 1054 illustrated in FIG. 5 is disposed between the command signal input terminal and the signal adjustment circuitry 1053a. However, the timing adjustment circuitry 1054 may be disposed between the command signal input terminal and the first amplifier unit 1051. In this layout, the command signal may be delayed by the delay circuitry. In this case as well, the timing adjustment circuitry 1054 can advance the timing of supplying the command signal to the signal adjustment circuitry 1053a.

### Second Modified Example

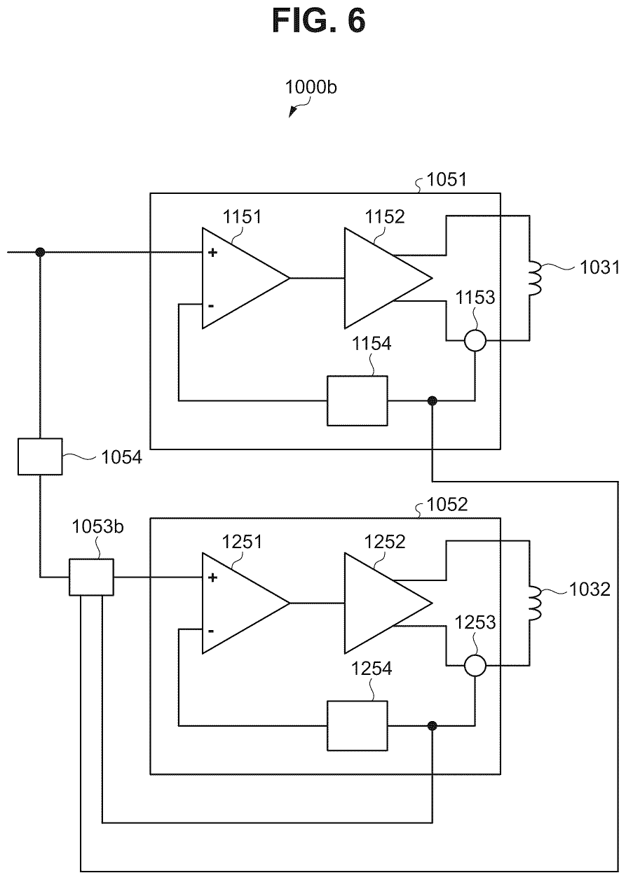

FIG. 6 is a diagram illustrating a circuitry configuration example of a gradient magnetic field system 1000b according to a second modified example.

A signal adjustment circuitry 1053b supplies the second amplifier unit 1052 with an adjusted signal corresponding to a calculated value calculated by Expression (2) below. In Expression (2), I₁ represents the output current of the first gradient magnetic field coil 1031 that is detected by the first current sensor 1153, I₂ represents the output current of the second gradient magnetic field coil 1032 that is detected by the second current sensor 1253, and G1, G2, and G3 each represent a gain. The gain can be as large as possible.

$$( {I}_{1} - {I}_{2} ) \times G 1 + G 2 \times \int ( {I}_{1} - {I}_{2} ) dt + G 3 \times d / dt ( {I}_{1} - {I}_{2} ) dt \qquad ( 2 )$$

The signal adjustment circuitry 1053b includes integration circuitry that implements the integral term represented in Expression (2), and differentiation circuitry that implements the differential term represented in Expression (2). In other words, the signal adjustment circuitry 1053b includes a low-pass filter and a high-pass filter. Accordingly, the signal adjustment circuitry 1053b supplies the second amplifier unit 1052 with the adjusted signal in which a mismatch between a high-frequency component and a low-frequency component is eliminated.

The second amplifier unit 1052 generates the second gradient magnetic field generation signal according to the adjusted signal. Specifically, the second amplifier unit 1052 controls the second gradient magnetic field generation signal based on a difference between the output current I₁ of the first gradient magnetic field coil 1031 and the output current I₂ of the first gradient magnetic field coil 1031, a value obtained by integrating the difference between the output current I₁ and the output current I₂, and a value obtained by differentiating the difference between the output current I₁ and the output current I₂. With this configuration, the second amplifier unit 1052 can generate the second gradient magnetic field generation signal in which a mismatch between a high-frequency component and a low-frequency component is eliminated.

Consequently, the signal adjustment circuitry 1053b can improve the degree of matching between the first gradient magnetic field generation signal and the second gradient magnetic field generation signal.

The gradient magnetic field system 1000b illustrated in FIG. 6 includes the timing adjustment circuitry 1054. However, the gradient magnetic field system 1000b may not include the timing adjustment circuitry 1054.

### Third Modified Example

The gradient magnetic field system 1000 according to the first embodiment, the gradient magnetic field system 1000a according to the first modified example, and the gradient magnetic field system 1000b according to the second modified example are each composed of analog circuitry. However, all or some of the gradient magnetic field systems 1000, 1000a, and 1000b may be composed of digital circuitry. For example, the first error amplifier 1151 and the second error amplifier 1251 may be implemented by a control integrated circuit (IC) that is digital circuitry.

For example, the gradient magnetic field systems 1000, 1000a, and 1000b are supplied with a command signal that is a digital signal. Analogue to digital (A/D) conversion circuitry converts a current signal that is an analog signal output from each of the first current sensor 1153 and the second current sensor 1253 into a digital signal.

The first error amplifier 1151 calculates an error between the command signal that is a digital signal and a current value that is a digital signal output from the first current sensor 1153. Further, the first error amplifier 1151 controls converter circuitry based on, for example, Proportional-Integral-Derivative (PID) control, so as to decrease the calculated error, thereby generating the signal to be supplied to the first gradient magnetic field coil 1031. The first power amplifier 1152 amplifies the signal output from the converter circuitry and outputs the amplified signal to the first gradient magnetic field coil 1031.

The second error amplifier 1251 calculates an error between the command signal that is a digital signal and a current value that is a digital signal output from the second current sensor 1253. Further, the second error amplifier 1251 controls the converter circuitry based on, for example, the PID control, so as to decrease the calculated error, thereby generating the signal to be supplied to the first gradient magnetic field coil 1031. The second power amplifier 1252 amplifies the signal output from the converter circuitry, and outputs the amplified signal to the second gradient magnetic field coil 1032.

According to at least one of the embodiments and the like described above, it is possible to prevent deterioration in image quality while improving a slew rate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A gradient magnetic field power supply apparatus comprising:
first circuitry configured to supply a current to a first coil based on a first signal corresponding to the current to be supplied to the first coil configured to generate a gradient magnetic field;
first processing circuitry configured to detect a current flowing through the first coil;
second processing circuitry configured to detect a current flowing through a second coil configured to generate a gradient magnetic field; and
second circuitry configured to supply a current to the second coil based on a second signal based on the first signal and a signal corresponding to a difference between the current detected by the first processing circuitry and the current detected by the second processing circuitry.

2. The gradient magnetic field power supply apparatus according to claim 1, wherein the second signal is a signal obtained by combining the first signal with the signal corresponding to the difference.

3. The gradient magnetic field power supply apparatus according to claim 1, wherein the first circuitry supplies the first coil with a current generated to decrease a difference between the first signal and a signal corresponding to the current detected by the first processing circuitry.

4. The gradient magnetic field power supply apparatus according to claim 1, wherein the second circuitry supplies the second coil with a current generated to decrease a difference between the second signal and a signal corresponding to the current detected by the second processing circuitry.

5. The gradient magnetic field power supply apparatus according to claim 1, wherein the second circuitry supplies the second coil with the current according to a product of the difference and a gain.

6. The gradient magnetic field power supply apparatus according to claim 1, further comprising timing adjustment circuitry configured to adjust a timing of supplying the first signal to the second circuitry.

7. The gradient magnetic field power supply apparatus according to claim 6, wherein the timing adjustment circuitry delays the timing of supplying the first signal to the second circuitry.

8. The gradient magnetic field power supply apparatus according to claim 6, wherein the timing adjustment circuitry advances the timing of supplying the first signal to the second circuitry.

9. The gradient magnetic field power supply apparatus according to claim 8, wherein the timing adjustment circuitry supplies the first signal to the second circuitry earlier than an output timing determined by an imaging sequence for capturing an image of a subject.

10. The gradient magnetic field power supply apparatus according to claim 1, wherein the second circuitry supplies the second coil with the current based on the difference, a value obtained by integrating the difference, and a value obtained by differentiating the difference.

11. The gradient magnetic field power supply apparatus according to claim 1, wherein the second circuitry generates the second signal according to an inverted signal of the first signal.

12. The gradient magnetic field power supply apparatus according to claim 1, wherein the first coil and the second coil each generate the gradient magnetic field in any one of three axial directions intersecting each other.

13. A gradient magnetic field power supply control method comprising:
supplying a current to a first coil based on a first signal corresponding to the current to be supplied to the first coil configured to generate a gradient magnetic field;
detecting a current flowing through the first coil;
detecting a current flowing through a second coil configured to generate a gradient magnetic field; and
supplying a current to the second coil based on a second signal based on the first signal and a signal corresponding to a difference between the detected current flowing through the first coil and the detected current flowing through the second coil.
